(19) United States
(12) Patent Application Publication
(10) Pub. No.: US 2010/0237379 A1
(43) Pub. Date: Sep. 23, 2010

(54) LIGHT EMITTING DEVICE

(76) Inventors: Wu-Cheng KUO, Hsinchu (TW); Jui-Ping Weng, Miaoli (TW); Tzu-Han Lin, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/407,385

(22) Filed: Mar. 19, 2009

(51) Int. Cl. H01L 33/00

(52) U.S. Cl. 257/99; 257/E33.066

(57) ABSTRACT

An embodiment of the invention provides a light emitting device, which includes: a first substrate made of a semiconductor material or a ceramic material; a first hole having extending direction from a first side toward an opposite second side and from a first surface toward an opposite second surface of the first substrate; a second hole having extending direction from the first side toward the second side and from the first surface toward the second surface; a light emitting element disposed overlying the first surface and having a first electrode and a second electrode; a first conducting layer overlying a first sidewall of the first hole and electrically connected to the first electrode; and a second conducting layer overlying a second sidewall of the second hole and electrically connected to the second electrode.

### BACKGROUND OF THE INVENTION

1. Field of the Invention

The present invention relates to a light emitting device and manufacturing method thereof, and in particular relates to side view type light emitting device.

2. Description of the Related Art

Light emitting diodes (LED) have become popular for general-purpose illumination applications due to characteristics such as, excellent durability, low power consumption, long operating life, no mercury content, and relatively higher efficiency.

LEDs can be classified into top view LEDs and side view LEDs according to the emitting direction of chips on the substrate thereof. Side view LEDs are used as a light source for small sized liquid crystal monitors, such as those used in mobile phones, PDAs, or notebooks. However, side view type LEDs are usually packaged by material made of polymer. Thus, heat dissipation becomes a more serious problem for designers. In addition, conventional side view type LEDs have electrodes on the opposite surface of the substrate wherein the light emitting diode chip is disposed, such that the package of the side view type LED is thick, thus limiting applications. Alternatively, a “side view form” LED may be formed by forming a reflective layer or reflective structure for turning the emitted light to a desired direction. However, size of the package of the LED is also relatively large.

Accordingly, an improved light emitting device is desirable.

### BRIEF SUMMARY OF THE INVENTION

In accordance with an embodiment of the invention, a light emitting device is provided, which includes: a first substrate made of a semiconductor material or a ceramic material; a first hole having extending directions from a first side toward an opposite second side and from a first surface toward an opposite second surface of the first substrate; a second hole having extending directions from the first side toward the second side and from the first surface toward the second surface; a light emitting element disposed overlying the first surface and having a first electrode and a second electrode; a first conducting layer overlying a first sidewall of the first hole and electrically connected to the first electrode; and a second conducting layer overlying a second sidewall of the second hole and electrically connected to the second electrode.

In accordance with another embodiment of the invention, a light emitting device is provided, which includes: a first substrate; a first hole having extending directions from a first side toward an opposite second side and from a first surface toward an opposite second surface of the first substrate; a second hole having extending direction from the first side toward the second side and from the first surface toward the second surface; a light emitting element disposed overlying the first surface and having a first electrode and a second electrode; a first conducting layer overlying a first sidewall of the first hole and electrically connected to the first electrode; and a second conducting layer overlying a second sidewall of the second hole and electrically connected to the second electrode.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1E are a set of diagrams showing the steps of forming a light emitting device in accordance with an embodiment of the present invention;

FIGS. 2A-2F are cross-sectional views showing the steps of forming a light emitting device corresponding to the embodiment shown in FIG. 1.

FIGS. 3A-3B are cross-sectional views showing sidewalls of holes in a substrate in accordance with embodiments of the present invention;

FIGS. 4A-4E are diagrams showing light emitting device in accordance with embodiments of the present invention;

FIGS. 5A-5B are top views showing the steps of cutting a substrate to obtain a light emitting device in accordance with embodiments of the present invention; and

FIGS. 6A-6C are three dimensional views of light emitting devices in accordance with embodiments of the present invention.

### DETAILED DESCRIPTION OF THE INVENTION

The present disclosure relates generally to a light emitting device and manufacturing method thereof and, more particularly, to a side view type light emitting device. It is understood, however, that the following disclosure provides many difference embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer include embodiments where the first and second layers are in direct contact and those where one or more layers are interposing the first and second layers.

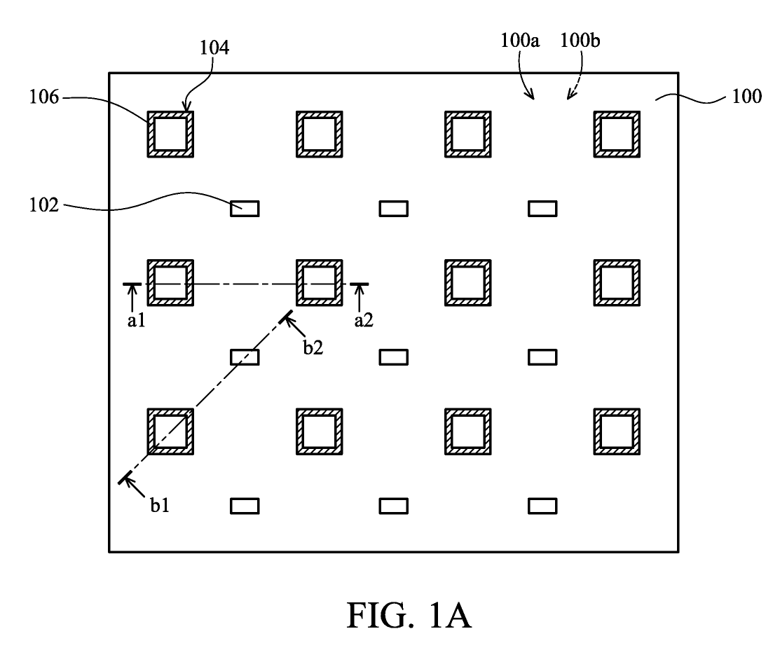

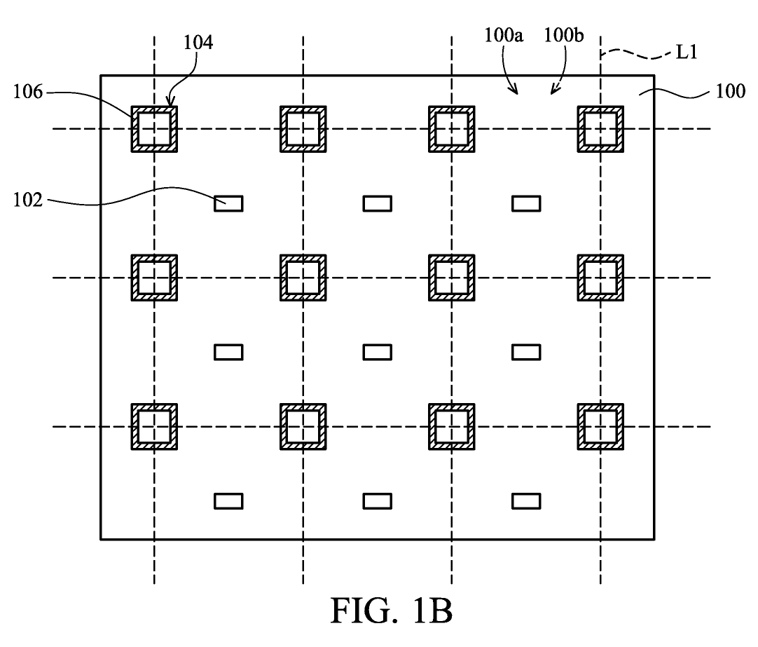

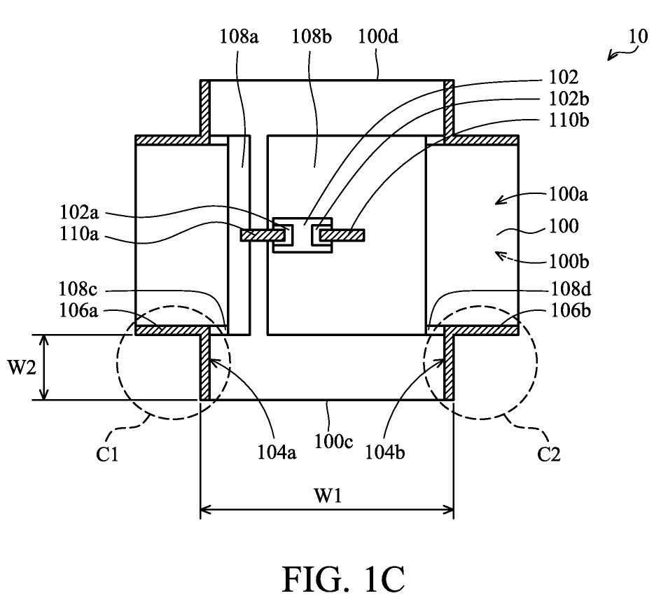

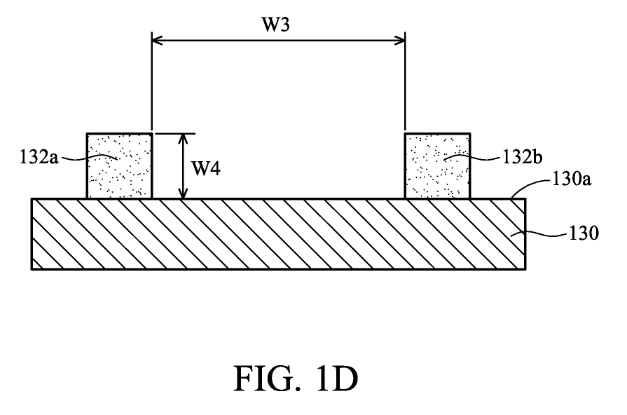

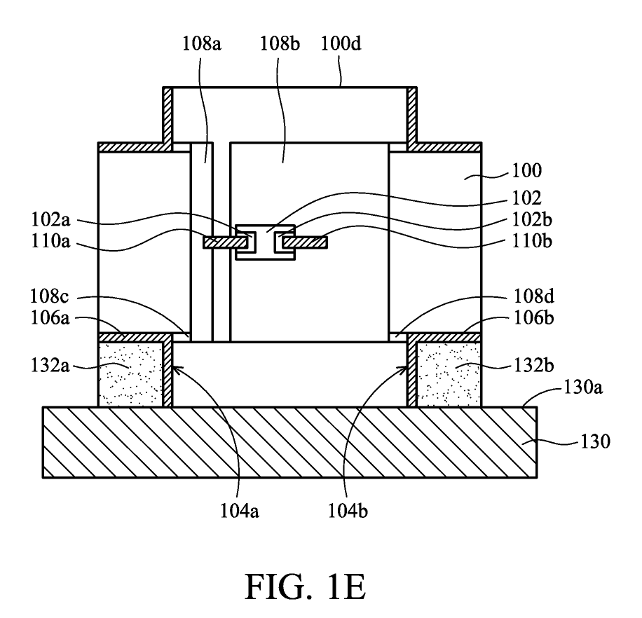

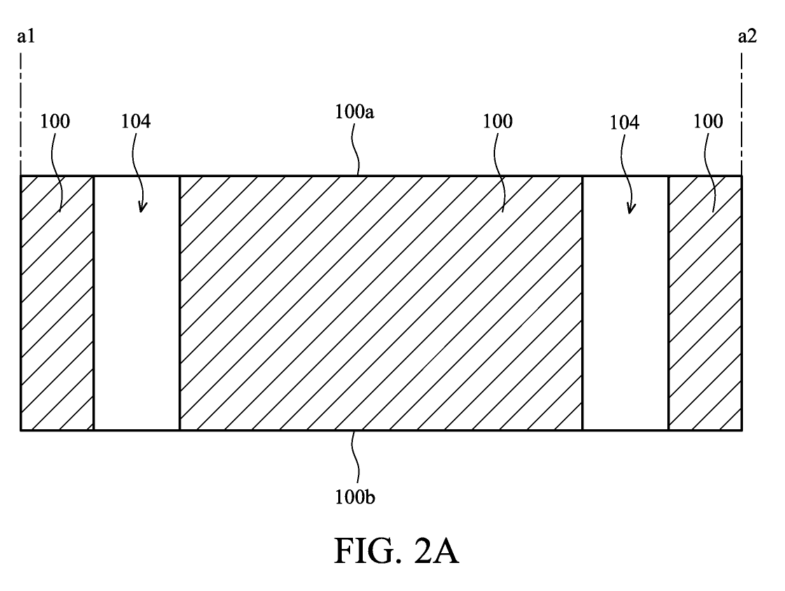

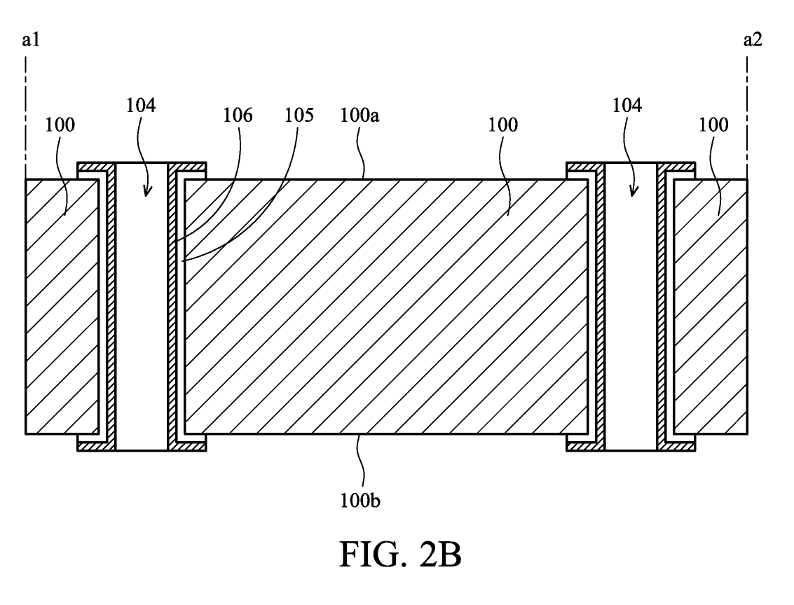

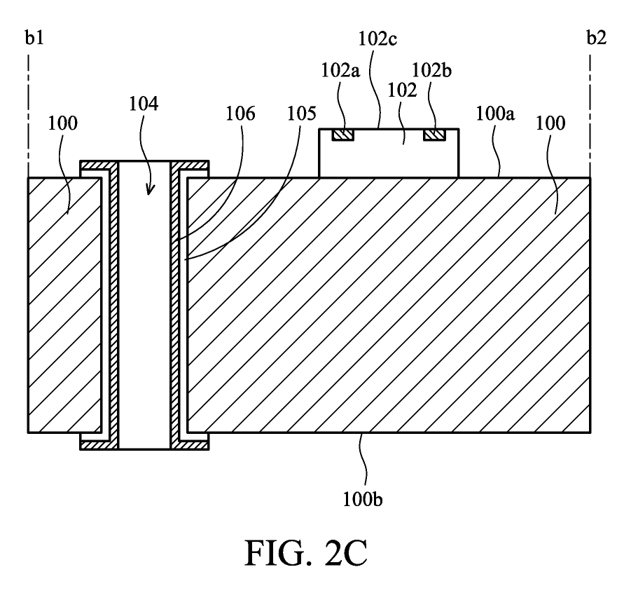

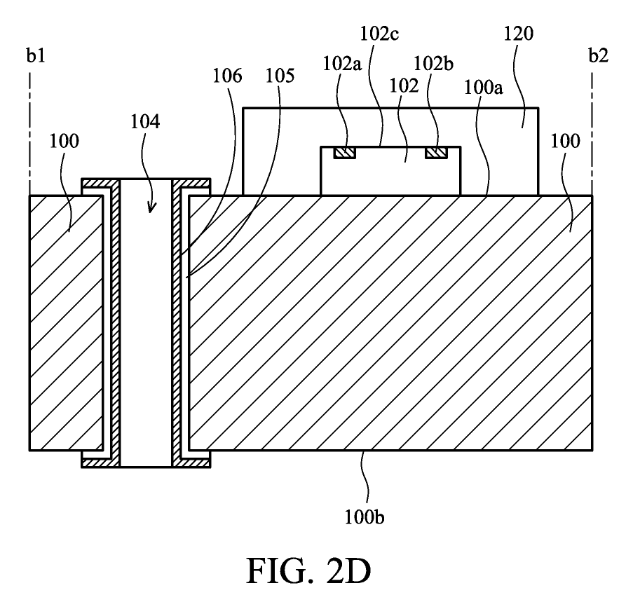

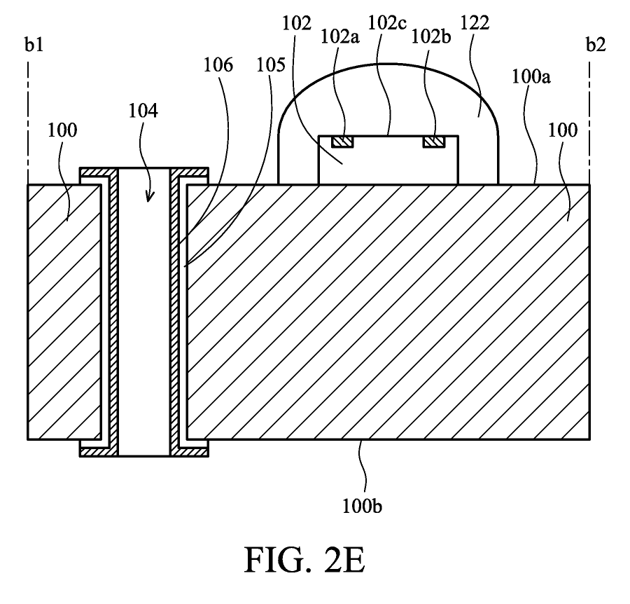

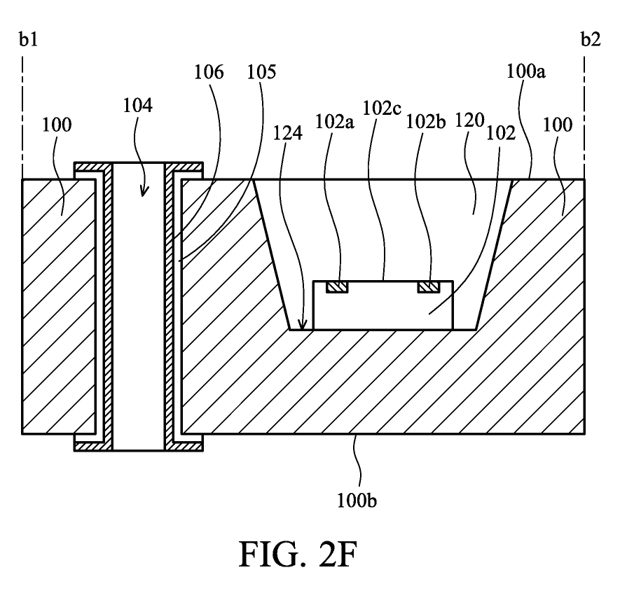

FIGS. 1A-1C are top views showing the steps of forming a light emitting device in accordance with an embodiment of the present invention. FIGS. 2A-2F are cross-sectional views showing the steps of forming a light emitting device corresponding to the embodiment shown in FIG. 1. First, referring to FIG. 1A, a substrate 100 is provided. The substrate 100 may include, but is not limited to, a semiconductor material, a ceramic material, or combinations thereof. In this embodiment, the substrate 100 is preferably a semiconductor wafer, such as a silicon wafer, or a substrate made of a ceramic material, such as an alumina substrate.

FIGS. 2A-2B are cross-sectional views showing the steps of forming the structure taken along the line a1-a2 of FIG. 1A. Referring to FIGS. 1A and 2A, at least two holes 104 extending from a first surface 100a toward an opposite second surface 100b are formed from the first surface 100a. The holes 104 may be formed by, for example, a photolithography and etching process. As shown in FIG. 2A, both holes near the left side and the right side penetrate the substrate 100 completely. In another embodiment, some of the holes 104 or all of the holes 104 do not penetrate the substrate 100 completely but only extend from the first surface 100a toward the second surface 100b to a predetermined depth.

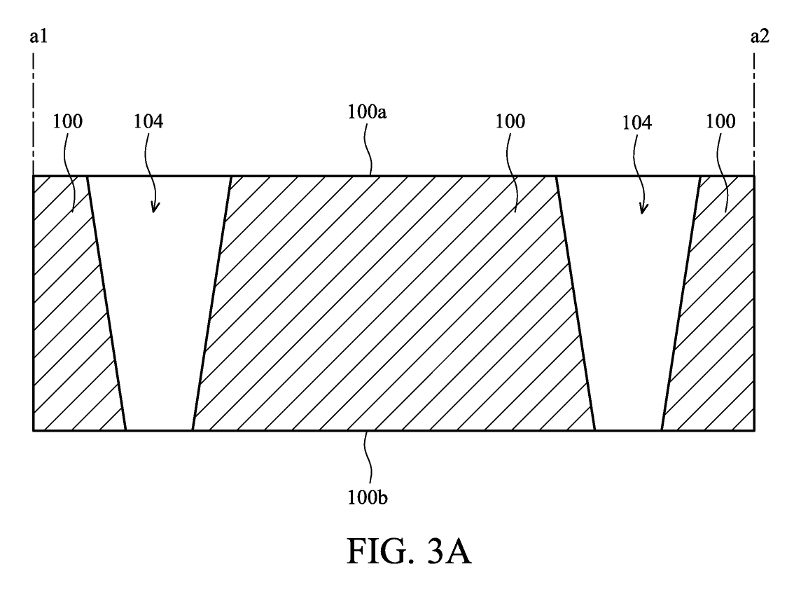

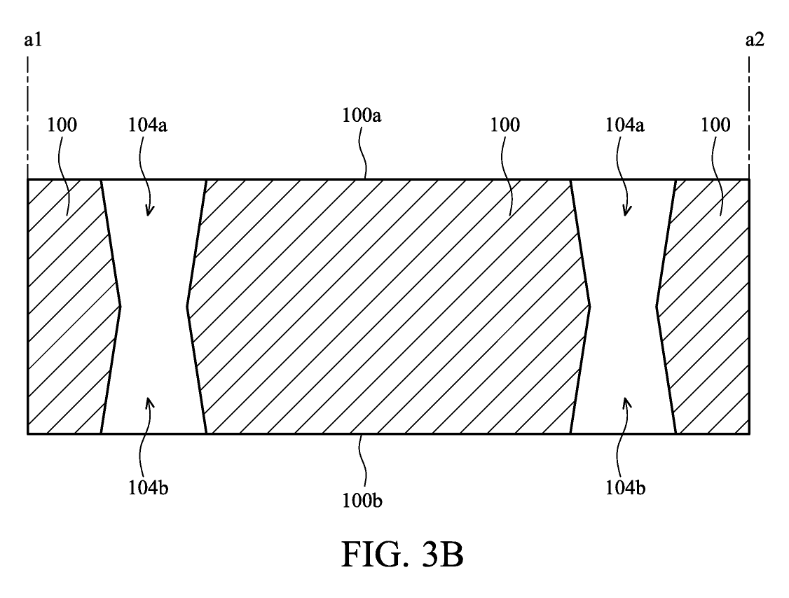

In addition, although sidewalls of the holes 104 shown in FIG. 2A are substantially perpendicular to the first surface 100a, embodiments of the invention are not limited to this. In another embodiment, sidewalls of the holes 104 may incline to the first surface 100a as shown in FIG. 3A. In yet another embodiment, the holes 104 may be formed by a two step etching process. As shown in FIG. 3B, sub-holes 104a are first formed from the first surface 100a to a predetermined depth. Then, sub-holes 104b are formed from the opposite second surface 100b to expose bottom portions of the sub-holes 104a. Sub-holes 104a and 104b together form holes that completely penetrate the substrate 100. In this embodiment, a sidewall of the sub-hole 104a tapers from the first surface 100a toward the second surface 100b to a predetermined depth while a sidewall of the sub-hole 104b tapers from the second surface 100b toward the first surface 100a to expose a bottom portion of the sub-hole 104a. In other words, a sidewall of a hole (including sub-holes 104a and 104b) shown in FIG. 3B tapers from the first surface 100a toward the second surface 100b and tapers from the second surface 100b toward the first surface 100a.

Referring to FIG. 1A and FIG. 2B, after forming the holes 104, patterned conducting layers 106 are formed overlying sidewalls of the holes 104. If the substrate 100, for example a silicon wafer, is conductive, it is preferable to form an insulating layer 105 overlying sidewalls of the holes 104 before forming the conducting layers 106. For simplicity, the insulating layer 105 is shown in FIGS. 2B-2C, but omitted in FIGS. 1A-1E. The insulating layer 105 may include, but is not limited to, a polymer material, silicon oxide, silicon nitride, silicon oxynitride, other suitable insulating materials, or combinations thereof. The insulating layer 105 may be formed by, for example, spin coating, chemical vapor deposition, physical vapor deposition, and/or other suitable methods.

After the insulating layer 105 is optionally formed, the conducting layer 106 is formed overlying the substrate 100. The conducting layer 106 may include, but is not limited to, a metal material, conducting polymer material, conducting ceramic material, or combinations thereof. In one embodiment, the conducting layer 106 is made of copper and formed by an electroplating process. In another embodiment, the conducting layer 106 may be formed by a physical vapor deposition, chemical vapor deposition, and/or plating process. A photolithography and etching process may then be performed for patterning the insulating layer 105 and the conducting layer 106. The patterned conducting layer 106 may substantially only cover sidewalls of the holes 104.

FIG. 2C shows a cross-sectional view taken along the line b1-b2 of FIG. 1A. Referring to FIGS. 1A and 2C, a plurality of light emitting elements 102 are then disposed overlying the first surface 100a of the substrate 100. The light emitting element 102 may be disposed overlying the substrate 100 by an adhesive layer (not shown). For example, the light emitting element 102 may be, but is not limited to, a light emitting diode or a chip having a light emitting diode formed therein. The light emitting element 102 has a light emerging surface 102c having a normal vector substantially parallel to a normal vector of the first surface 100a of the first substrate 100, wherein the light emitting element 102 emits light mainly from the light emerging surface 102c. The light emitting element 102 includes a first electrode 102a and a second electrode 102b used for receiving electrical power. The first electrode 102a and the second electrode 102b may be located on the same side of the light emitting element 102, such as that shown in FIG. 2C. In another embodiment, the first electrode 102a and the second electrode 102b may be located on different sides of the light emitting element 102. Further, when the light emitting element 102 is an LED device, the first electrode 102a has a conductivity opposite to that of the second electrode 102b. In one embodiment, the first electrode 102a is a p-type electrode and the second electrode 102b is an n-type electrode. In another embodiment, the first electrode 102a is an n-type electrode and the second electrode 102b is a p-type electrode.

Then, as shown in FIG. 2D, a patterned protecting layer 120 may be formed overlying each of the light emitting devices 102 by any suitable method. The protecting layer 120 may include, but is not limited to, silicone, epoxy, or combinations thereof. In another embodiment, a plurality of optical lens 122 may be formed overlying each of the light emitting elements 102 by any suitable method, as shown in FIG. 2E. The optical lens 122 may include, but is not limited to, silicone, epoxy, or combinations thereof. In yet another embodiment, as shown in FIG. 2F, a recess 124 may be formed on the substrate 100 by, for example, a photolithography and etching process. Then, the light emitting element 102 is disposed overlying a bottom portion of the recess 124 extending from the first surface 100a. A protecting layer 120 may be filled into the recess 124 to surround the light emitting element 102 for protection.

In addition, conducting elements, including bonding wires and/or conducting layers (not shown), may be formed before or/and after disposing of the light emitting element 102 to form electrical connections between the first electrode 102a and a conducting layer 106 in at least one of the holes 104. Similarly, the other conducting elements (not shown) may further be formed to electrically connect the second electrode 102b and a conducting layer 106 other than that electrically connecting the first electrode 102a in at least another one of the holes 104.

As shown in FIG. 1A, in this embodiment, a plurality of through holes 104 completely penetrating through the first surface 100a and the second surface 100b are periodically formed in the substrate 100. A plurality of conducting layers 106 are formed overlying sidewalls of the holes 104. A plurality of light emitting elements 102 are periodically disposed overlying the substrate 100. Each light emitting element 102 includes a first electrode 102a and a second electrode 102b (as shown in FIG. 2C). The first electrode 102a electrically connects at least one conducting layer 106 in at least one of the holes 104 through a conducting element (not shown) while the second electrode 102b electrically connects at least one conducting layer 106 other than that electrically connecting the first electrode 102a in at least another one of the holes 104 through another conducting elements (not shown).

Referring to FIG. 1B, the substrate 100 is then cut into a plurality of light emitting devices 10 along a plurality of predetermined scribe lines L1. In this embodiment, each hole 104 is intersected by two scribe lines L1. FIG. 1C shows a top view of a light emitting device 10 diced from the structure shown in FIG. 1B along the scribe lines L1.

As shown in FIG. 1C, the light emitting device 10 according to an embodiment of the present invention is provided. The light emitting device 10 includes a first substrate 100. The first substrate 100 may be, for example, made of a semiconductor material or a ceramic material. A light emitting element 102 is disposed overlying the first substrate 100. In this embodiment, a normal vector of a light emerging surface of the light emitting element 102 is substantially parallel to a normal vector of the first surface 100a of the first substrate 100. The light emitting element 102 includes a first electrode 102a and a second electrode 102b.

The light emitting device 10 includes a first hole 104a (or a first groove 104a) having extending direction from the first surface 100a toward the opposite second surface 100b and from a first side 100c toward an opposite second side 100d of the first substrate 100. In this embodiment, the first hole 104a penetrates the first substrate 100 completely. The light emitting device 10 further includes a second hole 104b (or a second groove 104b) having extending direction from the first surface 100a toward the opposite second surface 100b and from the first side 100c toward the opposite second side 100d of the first substrate 100. The first hole 104a and the second hole 104b are both located on the first side 100c of the substrate 100 and extended from the first surface 100a toward the opposite second surface 100b. In this embodiment, the second hole 104b also penetrates the first substrate 100 completely. In addition, in this embodiment, the first hole 104a and the second hole 104b are located at a first corner C1 and a second corner C2, respectively. It should be appreciated that the first hole 104a and/or the second hole 104b are not limited to be located at the corners C1 and/or C2, respectively.

Still referring to FIG. 1C, the light emitting device 10 includes a first conducting layer 106a overlying a first sidewall of the first hole 104a and a second conducting layer 106b overlying a second sidewall of the second hole 104b. Through conducting elements, the first conducting layer 106a and the second conducting layer 106b can electrically connect the first electrode 102a and the second electrode 102b of the light emitting element 102, respectively. In this embodiment, conducting layers 108a, 108c, and 110a are formed overlying the first surface 100a for forming the electrical connection between the first electrode 102a and the first conducting layer 106a. A conducting layer 108b underlying the light emitting element 102, a conducting layer 108d overlying the first surface 100a, and a conducting layer 110b are formed for forming the electrical connection between the second electrode 102b and the second conducting layer 106b. In another embodiment, the conducting layers 110a and 110b may be substituted by bonding wires. The conducting layers 106a and 106b in the holes 104a and 104b may serve as “side electrodes” of the light emitting device 10.

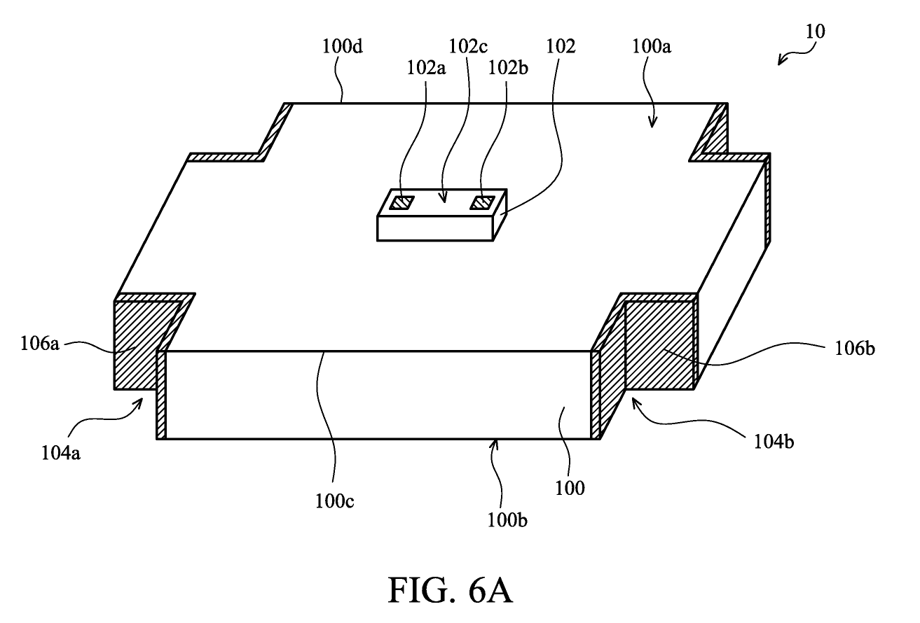

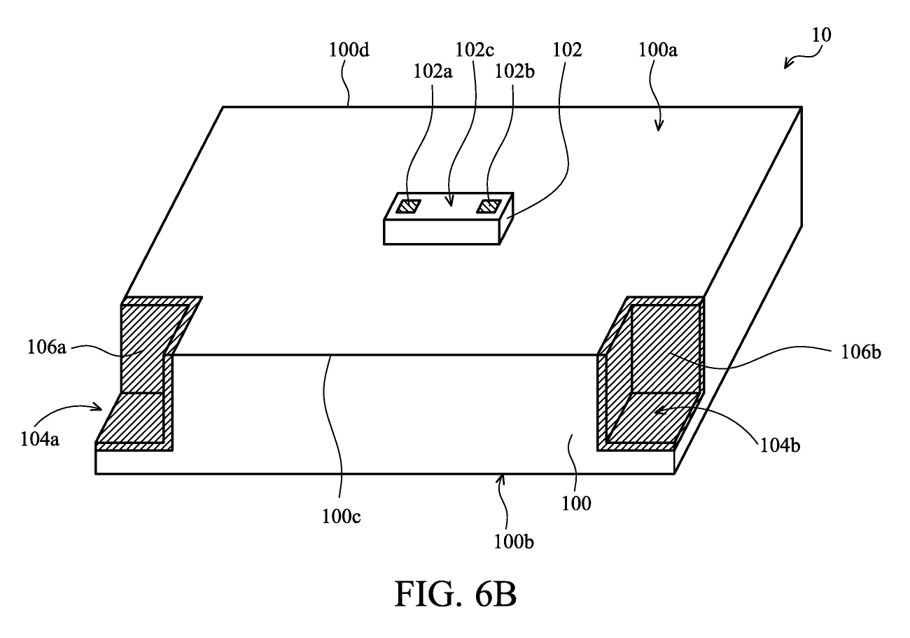

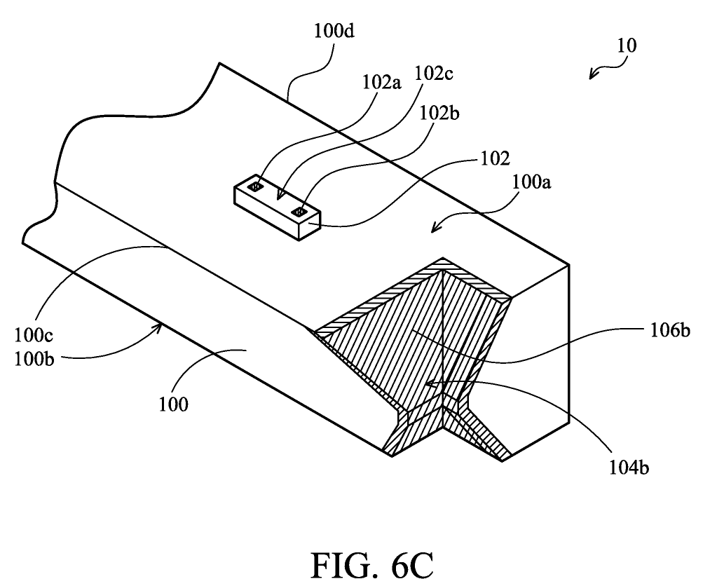

FIG. 6A shows a three dimensional view of a light emitting device 10 corresponding to the embodiment shown in FIG. 1C. Through conducting elements, such as that shown in FIG. 1C, the first electrode 102a and the second electrode 102b electrically connect the first conducting layer 106a and the second conducting layer 106 b, respectively. For simplicity, conducting elements are not shown in FIG. 6A. In this embodiment, the sidewall of the first hole 104a and the sidewall of the second hole 104b are substantially perpendicular to the first surface 100a. The conducting layers 106a and 106b serve as “side electrodes” of the light emitting device 10, which may be used to electrically contact other conducting elements.

For example, the light emitting device 10 may further be bonded on another substrate, such as a printed circuit board or a package substrate. Referring to FIG. 1D, a second substrate 130 is provided. In one embodiment, the second substrate 130 is a printed circuit board. The second substrate 130 includes at least a first conducting element 132a and at least a second conducting element 132b overlying a surface 130a of the second substrate 130. The first and second conducting elements 132a and 132b are, for example, conducting bumps used for electrically connecting the “side electrodes” of the light emitting device 10. In this embodiment, each of the first conducting element 132a and the second conducting element 132b has a thickness W4 and are separated with a distance W3. Also referring to FIG. 1C, the distance W3 substantially equals to a distance W1 between the first conducting layer 106a and the second conducting layer 106b. The thickness W4 substantially equals to a distance W2 between the conducting layer 106a or 106b and the first side 100c of the substrate 100.

Referring to FIG. 1E, the light emitting device 10 is then disposed overlying the second substrate 130. Because the distance W3 substantially equals to the distance W1 and the thickness W4 substantially equals to the distance W2, the first conducting element 132a and the second conducting element 132b fit into the holes 104a and 104b, respectively. In this embodiment, a portion of the first conducting element 132a and a portion of the second conducting element 132b are in the first hole 104a and the second hole 104b, respectively. In another embodiment, all of the first conducting element 132a or/and the second conducting element 132b is in the first hole 104a or/and the second hole 104b, respectively. The first conducting element 132a and the second conducting element 132b directly contact the first conducting layer 106a (or first side electrode) and the second conducting layer 106b (or second side electrode), respectively. Thus, the first conducting element 132a can electrically connect the first electrode 102a of the light emitting element 102 through the first conducting layer 106a and other conducting elements including, for example, the conducting layers 108c and 108a. Similarly, the second conducting element 132b can electrically connect the second electrode 102b of the light emitting element 102 through the second conducting layer 106b and other conducting elements including, for example, the conducting layers 108d and 108b. In addition, as shown in FIG. 1E, the normal vector of the first surface 100a of the first substrate 100 is substantially perpendicular to a normal vector of the surface 130a of the second substrate 130. Therefore, a side view type light emitting device having side electrodes is formed according to an embodiment of the invention.

It should be appreciated that the first hole 104a and the second hole 104b are not limited to completely penetrate the first substrate 100. In one embodiment, the first hole 104a and the second hole only extend from the first surface 100a toward the second surface 100b of the first substrate 100 to a predetermined depth. It should be noted that after cutting the substrate 100 along the scribe lines traveling through the holes, the conducting layers 106a and 106b overlying sidewalls of the holes 104a and 104b can still serve as the “side electrodes” of the light emitting device 10. FIG. 6B shows a three dimensional view of such a light emitting device 10 according to an embodiment of the invention. As shown in FIG. 6B, even if the holes 104a and 104b do not penetrate the first substrate 100 completely, the conducting layers 106a and 106b still can serve as the “side electrodes” of the light emitting device 10. Similar to the structure shown in FIG. 1E, the light emitting device 10 shown in FIG. 6B can also be disposed overlying a second substrate, such as a printed circuit board.

FIG. 6C shows a three dimensional view of a light emitting device 10 having holes similar to that shown in FIG. 3B.

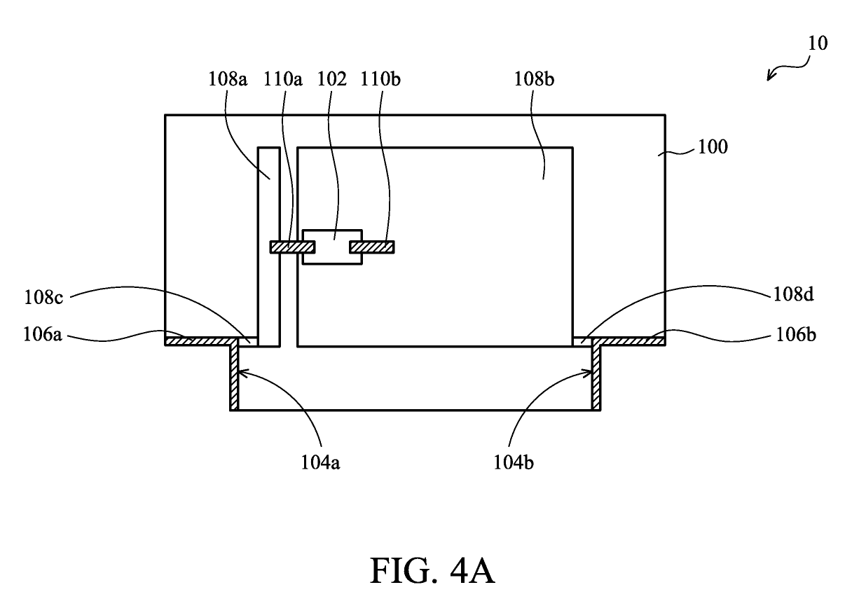

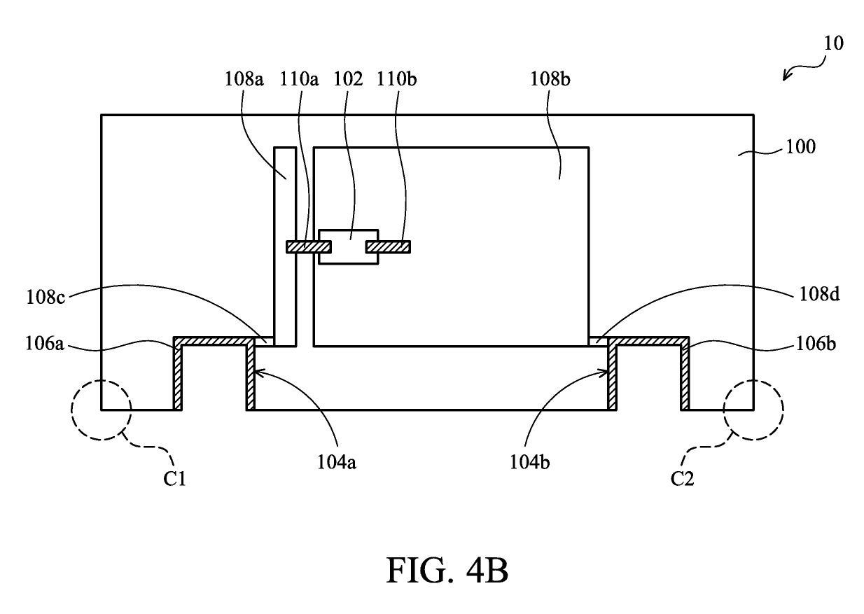

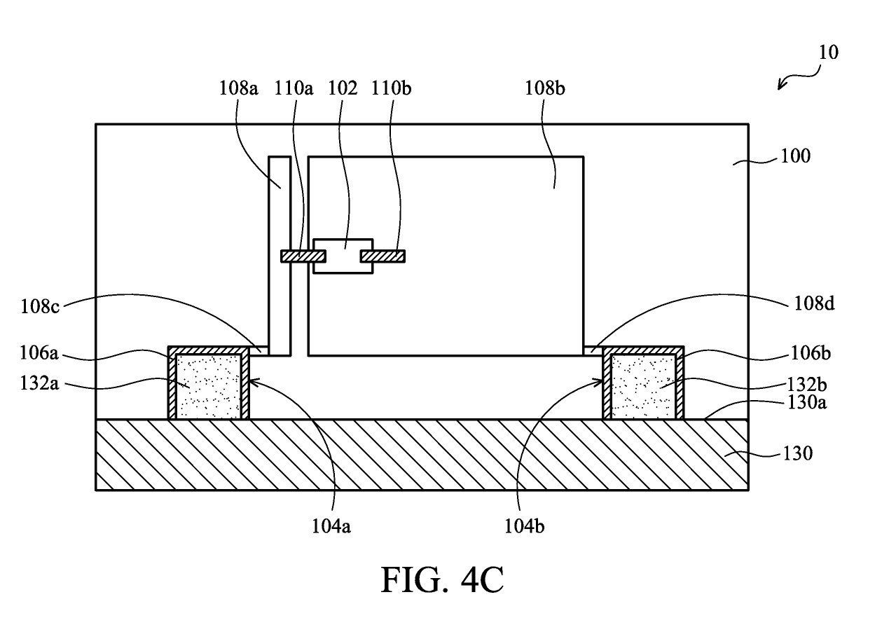

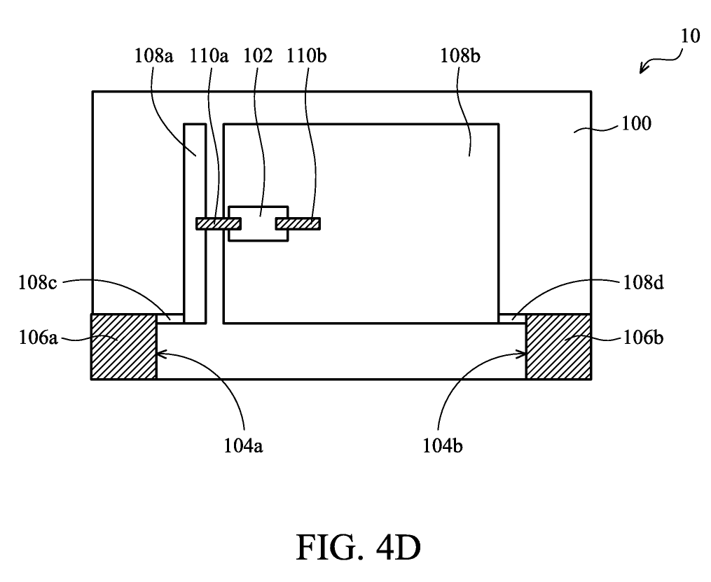

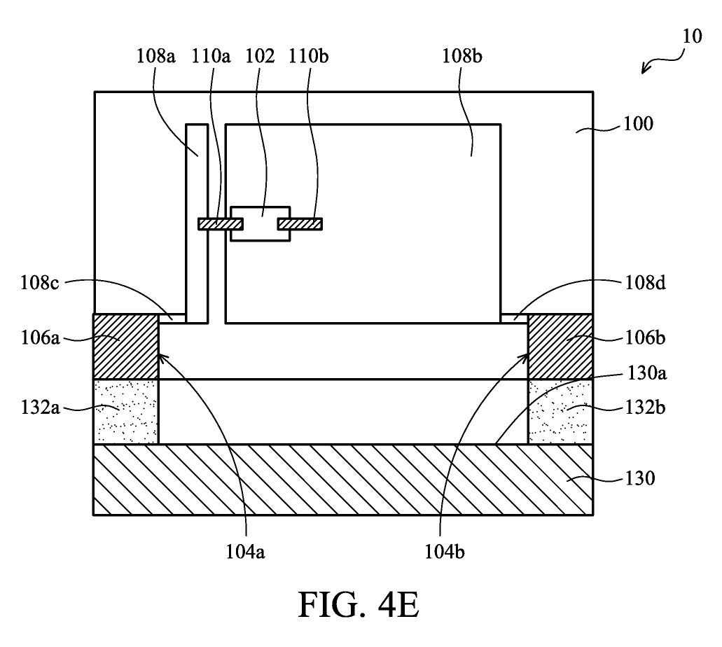

In addition, although the light emitting device 10 of the embodiment shown in FIG. 1C has four holes, embodiments of the invention are not limited thereto. FIGS. 4A-4E are diagrams showing light emitting devices in accordance with different embodiments of the present invention. Referring to FIG. 4A, the light emitting device 10 may also be diced from the structure shown in FIG. 1B along the scribe lines L1, wherein the light emitting device 10 near a peripheral merely has two holes.

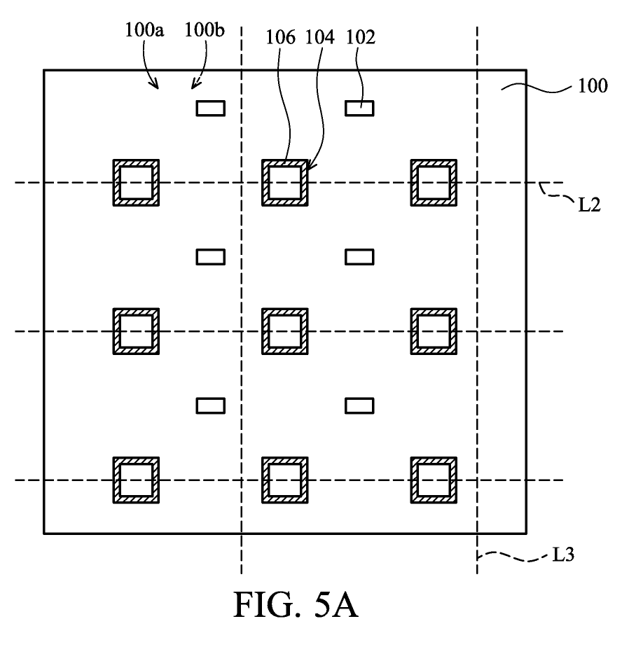

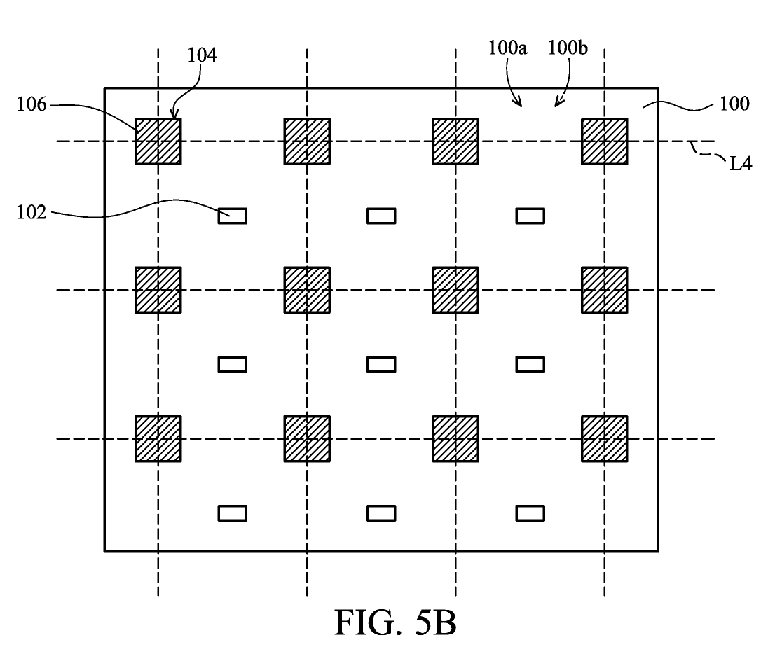

The light emitting device may not only be diced from the structure shown in FIG. 1B along the scribe lines L1, but also cut from a similar structure along scribe lines L2 and L3, as shown in FIG. 5A. Each scribe line L2 travels through at least a hole 104 while each scribe line L3 merely travels through the substrate 100 without traveling through the holes 104. FIG. 4B shows a top view of a light emitting device 10 diced from the structure shown in FIG. 5A along the scribe lines L2 and L3 in accordance with an embodiment of the invention. As shown in FIG. 4B, the first hole 106a and the second hole 106b are no longer located at the first corner C1 and the second corner C2 compared with the structure shown in FIG. 1C. Similar to the structure shown in FIG. 1E, the light emitting device 10 shown in FIG. 4B may also be disposed overlying a second substrate 130 having at least a first conducting element 132a and a second conducting element 132b formed thereon, as shown in FIG. 4C. In this embodiment, the conducting layers 106a and 106b serve as the “side electrodes” of the light emitting device 10.

FIG. 5B shows a top view of an embodiment of the invention. As shown in FIG. 5B, similar to that shown in FIGS. 1A and 5A, the substrate 100 includes a plurality of light emitting elements 102 thereon and a plurality of holes 104 therein. However, different from the previous mentioned embodiments, the conducting layers 106 are not only overlying sidewalls of the holes 104 but also substantially and completely fill the holes. Then, similar to the previous mentioned embodiments, the substrate 100 is cut into a plurality of light emitting devices 10 along predetermined scribe lines L4, as shown in FIG. 5B. FIG. 4D shows a top view of one of the light emitting device 10 cut from the structure shown in FIG. 5B. As shown in FIG. 4D, both the first conducting layer 106a and the second conducting layer 106b completely fill the first hole 104a and the second hole 104b, respectively. In another embodiment, it is possible that only one of the first hole 104a and the second hole 104b is completely filled with a conducting layers.

The light emitting device 10 shown in FIG. 4D may also be disposed overlying a second substrate 130 having at least a first conducting element 132a and a second conducting element 132b formed thereon, as shown in FIG. 4E. In this embodiment, the conducting layers 106a and 106b serve as the “side electrodes” of the light emitting device 10. Compared with other conventional side view type light emitting device having electrodes on the opposite surface of the substrate carrying the light emitting element, the circuit board electrically connecting the light emitting element may be disposed from the back to the side of the substrate in the light emitting device of an embodiment of the invention having the “side electrodes”. Thus, the second substrate (or package substrate) of a light emitting device according to the invention may be much thinner than the conventional side view type light emitting device, increasing potential applications.

In an embodiment, a plurality of light emitting devices 10 may be obtained from a single wafer having a plurality of light emitting elements 102 formed or disposed thereon. Then the light emitting devices 10 having at least two “side electrodes” in a single side may be further disposed overlying a second substrate having a plurality of conducting elements formed thereon. The second substrate may include a printed circuit board having a plurality of metal bumps. Thus, a plurality of side view type light emitting devices may be disposed overlying a single printed circuit board.

Through dicing the substrate, having a plurality of light emitting elements thereon and a plurality of vias or through substrate vias formed therein, along scribe lines travel through the vias or the through substrate vias, a plurality of light emitting devices having the “side electrodes” can be fabricated. Embodiments of the present invention have advantageous features. Throughput of the light emitting device of a single substrate, such as a wafer, may be improved. Although the embodiment is particularly suitable for the application of side view type light emitting devices, the light emitting element of the embodiment may be substituted by other semiconductor devices, such as a semiconductor chip, a photosensor chip, a photovoltaic chip, and the like.

While the invention has been described by way of example and in terms of the embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting device, comprising:
a first substrate made of a semiconductor material or a ceramic material;
a first hole having extending direction from a first side toward an opposite second side and from a first surface toward an opposite second surface of the first substrate;
a second hole having extending direction from the first side toward the second side and from the first surface toward the second surface;
a light emitting element disposed overlying the first surface and having a first electrode and an second electrode;
a first conducting layer overlying a first sidewall of the first hole and electrically connected to the first electrode; and
a second conducting layer overlying a second sidewall of the second hole and electrically connected to the second electrode.

2. The light emitting device as claimed in claim 1, wherein the first hole is located at a first corner.

3. The light emitting device as claimed in claim 1, wherein the second hole is located at a second corner.

4. The light emitting device as claimed in claim 1, wherein a normal vector of a light emerging surface of the light emitting element is substantially parallel to a first normal vector of the first surface of the first substrate.

5. The light emitting device as claimed in claim 4, further comprising:
a second substrate;
at least a first conducting element overlying a surface of the second substrate; and
at least a second conducting element overlying the surface of the second substrate,
wherein:
the first substrate is disposed overlying the second substrate;
the first normal vector is substantially perpendicular to a second normal vector of the surface of the second substrate;
the first conducting element directly contacts the first conducting layer; and
the second conducting element directly contacts the second conducting layer.

6. The light emitting device as claimed in claim 5, wherein at least a portion of the first conducting element or the second conducting element is in the first hole or the second hole, respectively.

7. The light emitting device as claimed in claim 5, wherein the first conducting layer or the second conducting layer completely fills the first hole or the second hole, respectively.

8. The light emitting device as claimed in claim 5, wherein a distance between the first conducting element and the second conducting element substantially equals to a distance between the first conducting layer and the second conducting layer.

9. The light emitting device as claimed in claim 5, wherein the second substrate is a printed circuit board.

10. The light emitting device as claimed in claim 1, further comprising an insulating layer between the first substrate and the first conducting layer or the second conducting layer.

11. The light emitting device as claimed in claim 1, wherein the first hole or the second hole completely penetrates the first substrate.

12. The light emitting device as claimed in claim 1, wherein the light emitting element comprises a light emitting diode.

13. The light emitting device as claimed in claim 1, wherein the first sidewall of the first hole or the second sidewall of the second hole is substantially perpendicular to the first surface.

14. The light emitting device as claimed in claim 1, wherein the first sidewall of the first hole or the second sidewall of the second hole inclines to the first surface.

15. The light emitting device as claimed in claim 1, wherein the first sidewall of the first hole or the second sidewall of the second hole tapers from the first surface toward the second surface and tapers from the second surface toward the first surface.

16. The light emitting device as claimed in claim 1, further comprising a protecting layer overlying the light emitting element.

17. The light emitting device as claimed in claim 1, further comprising an optical lens overlying the light emitting element.

18. The light emitting device as claimed in claim 1, wherein the light emitting element is disposed overlying a bottom portion of a cavity extending from the first surface of the first substrate.

19. A light emitting device, comprising:
a first substrate;
a first hole having extending direction from a first side toward an opposite second side and from a first surface toward an opposite second surface of the first substrate;
a second hole having extending direction from the first side toward the second side and from the first surface toward the second surface;
a light emitting element disposed overlying the first surface and having a first electrode and an second electrode;
a first conducting layer overlying a first sidewall of the first hole and electrically connected to the first electrode; and
a second conducting layer overlying a second sidewall of the second hole and electrically connected to the second electrode.

20. The light emitting device as claimed in claim 19, further comprising:
a second substrate;
at least a first conducting element overlying a surface of the second substrate; and
at least a second conducting element overlying the surface of the second substrate, wherein:
the first substrate is disposed overlying the second substrate;
a first normal vector of the first surface of the first substrate is substantially perpendicular to a second normal vector of the surface of the second substrate;
the first conducting element directly contacts the first conducting layer; and
the second conducting element directly contacts the second conducting layer.
